(19) United States
(12) Patent Application Publication
(10) Pub. No.: US 2025/0355450 A1
(43) Pub. Date: Nov. 20, 2025

(54) REMOTE CONTROL METHOD OF GAS SUPPLY EQUIPMENT

(71) Applicant: SAMSUNG ELECTRONICS CO., LTD., Suwon-si (KR)

(72) Inventors: Junmo Park, Suwon-si (KR); Byeongcheol Jang, Seongnam-si (KR); Seungjae Pyeon, Pyeongtaek-si (KR); Juyoung Park, Anseong-si (KR); Hongyun Kwon, Suwon-si (KR); Yongduk Park, Anseong-si (KR); Hyunjin Kim, Pyeongtaek-si (KR); Sangtac Jung, Seongnam-si (KR)

(73) Assignees: SAMSUNG ELECTRONICS CO., LTD., Suwon-si (KR); KC CO., LTD., Anseong-si (KR); Wonik Holdings Co., Ltd., Pyeongtaek-si (KR)

(21) Appl. No.: 19/210,837

(22) Filed: May 16, 2025

(30) Foreign Application Priority Data
May 17, 2024 (KR) 10-2024-0064827

(51) Int. Cl. G05D 7/06; G01D 4/00

(52) U.S. Cl. CPC G05D 7/0635; G01D 4/002

(57) ABSTRACT

Provided is a method of remotely controlling gas supply equipment, the method including: checking an operation allowance condition of a first operation of the gas supply equipment using a remote control server; checking a remote control authority using the remote control server, checking whether performance of the first operation is possible; controlling the gas supply equipment to perform the first operation; and initializing a received signal using the remote control server.

### CROSS-REFERENCE TO RELATED APPLICATION

This application is based on and claims priority to Korean Patent Application No. 10-2024-0064827, filed on May 17, 2024, in the Korean Intellectual Property Office, the disclosure of which is incorporated by reference herein in its entirety.

### BACKGROUND

### 1. Field

The disclosure relates to a method of remotely controlling gas supply equipment.

### 2. Description of Related Art

Various kinds of gases are used for semiconductor manufacturing and production. To stably supply such gases in a semiconductor manufacturing process, gas supply equipment may be provided. As a semiconductor production process becomes more complex, and semiconductor production equipment becomes larger, the area occupied by gas supply equipment is progressively expanding. Therefore, more human resources and more time are consumed in individually controlling a plurality of gas supply equipment.

### SUMMARY

Provided is a method of remotely controlling gas supply equipment and securing the reliability and economic feasibility of the operation of such equipment.

According to an aspect of the disclosure, a method of remotely controlling gas supply equipment includes: checking an operation allowance condition of a first operation of the gas supply equipment using a remote control server; checking a remote control authority using the remote control server; checking whether performance of the first operation is possible; controlling the gas supply equipment to perform the first operation; and initializing a received signal using the remote control server.

According to an aspect of the disclosure, a method of remotely controlling gas supply equipment includes: selecting, using a control apparatus, a first operation of the gas supply equipment; checking, using a remote control server, whether there is authority to perform the first operation; checking, using an equipment controller, whether performance of the first operation is possible; transmitting, using the remote control server, a first operation performance signal to the gas supply equipment; controlling the gas supply equipment to perform the first operation; and checking, using the equipment controller, whether performance of the first operation is completed.

According to an aspect of the disclosure, a method of remotely controlling gas supply equipment includes: checking an operation allowance condition of a first operation of the gas supply equipment using a remote control server; checking a remote control authority using the remote control server; checking whether performance of the first operation is possible; controlling the gas supply equipment to perform the first operation; and initializing a received signal using the remote control server, wherein the checking the operation allowance condition includes checking the operation allowance condition of each of a plurality of operations including the first operation, and displaying, through a display, the allowance condition of the first operation and an indication of whether performance of the first operation is possible, wherein the checking of whether the performance of the first operation is possible includes: identifying the gas supply equipment associated with the first operation using the remote control server; transmitting a first command code, corresponding to the first operation, to the gas supply equipment; and transmitting, by the gas supply equipment to the remote control server, a first feedback including the indication of whether the performance of the first operation is possible, wherein the checking the remote control authority includes: based on there not being remote control authority, outputting an indicator on the display that there is no authority; and based on there being remote control authority, checking the gas supply equipment associated with the first operation and transmitting a first operation performance signal to the gas supply equipment, wherein the performing the first operation includes transmitting a second feedback to the remote control server based on performance of the first operation being completed, the first feedback further including a signal that preparation of the first operation is completed, and the second feedback including a signal that the performance of the first operation is completed, wherein the first operation includes one or more of a purge start, a purge cancellation, a purge restart, and remote valve control before or after replacement of a cylinder of the gas supply equipment, wherein a first code corresponding to the first operation is set and stored in the remote control server and the gas supply equipment, and the first code is used to identify an operation performed by each of the remote control server and the gas supply equipment, wherein the first operation further includes a combination of one or more individual operations, and at least one signal transmitted or received between the remote control server and the gas supply equipment related to performance of the combination of the one or more individual operations includes a predetermined code, and wherein each of the remote control server and the gas supply equipment is configured to check the predetermined code included in the transmitted or received signal.

According to an aspect of the disclosure, a control system includes: a control apparatus including: first memory storing one or more first instructions; at least one control apparatus processor configured to execute the one or more first instructions; a first communication interface; an input interface; and a display; a remote control server including: second memory storing one or more second instructions; at least one remote control server processor configured to execute the one or more second instructions; and a second communication interface; gas supply equipment including: at least one of a gas bottle and a valve; and at least one equipment controller including: third memory storing one or more third instructions; at least one controller processor configured to execute the one or more third instructions; and a third communication interface; wherein the one or more second instructions, when executed by the at least one remote controller server processor, cause the remote control server to: check an operation allowance condition of a first operation of the gas supply equipment; check a remote control authority; and send to the equipment controller, through the second communication interface, a request for a status of the gas supply equipment; wherein the one or more third instructions, when executed by the at least one controller processor, cause the equipment controller to: identify whether performance of the first operation is possible; and based on identifying that performance of the first operation is possible, transmit first feedback, through the third communication interface, to the remote control server indicating that performance of the first operation is possible; wherein the one or more second instructions, when executed by the at least one remote controller server processor, further cause the remote control server to, based on receiving the first feedback, transmit through the second communication interface a signal causing the gas supply equipment to perform the first operation; wherein the one or more third instructions, when executed by the at least one controller processor, further cause the equipment controller to: based on receiving, through the third communication interface, the signal causing the gas supply equipment to perform the first operation: control the gas supply equipment to perform the first operation; and based on the first operation being performed, transmit second feedback, through the third communication interface, to the remote control server indicating that performance of the first operation is complete; and wherein the one or more second instructions, when executed by the at least one remote controller server processor, further cause the remote control server to, based on receiving the second feedback, transmit a received signal to the control apparatus.

The disclosure is not limited to the aforesaid, but other objects and features not described herein will be clearly understood by those of ordinary skill in the art from the description below.

### BRIEF DESCRIPTION OF DRAWINGS

The above and other aspects and features of certain embodiments of the present disclosure will be more clearly understood from the following detailed description taken in conjunction with the accompanying drawings, in which:

FIG. 1 is a schematic diagram illustrating apparatuses involved in a method of remotely controlling gas supply equipment according to one or more embodiments;

FIG. 2 is a flowchart for describing a method of remotely controlling gas supply equipment according to one or more embodiments;

FIG. 3 is a diagram illustrating an example of an input/output apparatus for a method of remotely controlling gas supply equipment, according to one or more embodiments;

FIG. 4 is a table showing a portion of an equipment operation allowance condition according to one or more embodiments;

FIG. 5 is a block diagram illustrating a configuration of a control apparatus in a method of remotely controlling gas supply equipment, according to one or more embodiments;

FIGS. 6A and 6B are tables showing individual operations capable of being performed in gas supply equipment and hexa codes assigned to the individual operations according to one or more embodiments; and

FIG. 7 is a flowchart for describing a method of transferring a signal by using an equipment controller and a remote control server in a method of remotely controlling gas supply equipment, according to one or more embodiments.

### DETAILED DESCRIPTION

Hereinafter, one or more embodiments will be described in detail with reference to the accompanying drawings.

One or more embodiments may be provided to convey the scope of the disclosure to those of ordinary skill in the art. The following one or more embodiments may be modified into various forms, and the disclosure is not limited to the following one or more embodiments.

In the drawings, the thickness or size of each layer may be exaggerated for convenience of description and clarity. In the following description, like reference numerals refer to like elements throughout the specification.

Terms such as “unit”, “module”, “member”, and “block” may be embodied as hardware or software. As used herein, a plurality of “units”, “modules”, “members”, and “blocks” may be implemented as a single component, or a single “unit”, “module”, “member”, and “block” may include a plurality of components.

It will be understood that when an element is referred to as being “connected” with or to another element, it can be directly or indirectly connected to the other element, wherein the indirect connection includes “connection via a wireless communication network”.

Also, when a part “includes” or “comprises” an element, unless there is a particular description contrary thereto, the part may further include other elements, not excluding the other elements.

Throughout the description, when a member is “on” another member, this includes not only when the member is in contact with the other member, but also when there is another member between the two members.

As used herein, the expressions “at least one of a, b or c” and “at least one of a, b and c” indicate “only a,” “only b,” “only c,” “both a and b,” “both a and c,” “both b and c,” and “all of a, b, and c.”

It will be understood that, although the terms “first”, “second”, “third”, etc., may be used herein to describe various elements, is the disclosure should not be limited by these terms. These terms are only used to distinguish one element from another element.

As used herein, the singular forms “a,” “an” and “the” are intended to include the plural forms as well, unless the context clearly indicates otherwise.

With regard to any method or process described herein, an identification code may be used for the convenience of the description but is not intended to illustrate the order of each step or operation. Each step or operation may be implemented in an order different from the illustrated order unless the context clearly indicates otherwise. One or more steps or operations may be omitted unless the context of the disclosure clearly indicates otherwise.

The various actions, acts, blocks, steps, or the like in the flow diagrams may be performed in the order presented, in a different order, or simultaneously. Further, in one or more embodiments, some of the actions, acts, blocks, steps, or the like may be omitted, added, modified, skipped, or the like without departing from the scope of the disclosure.

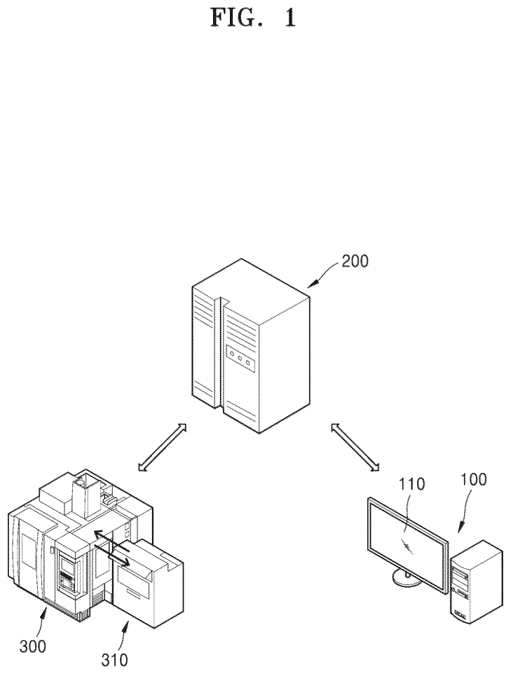

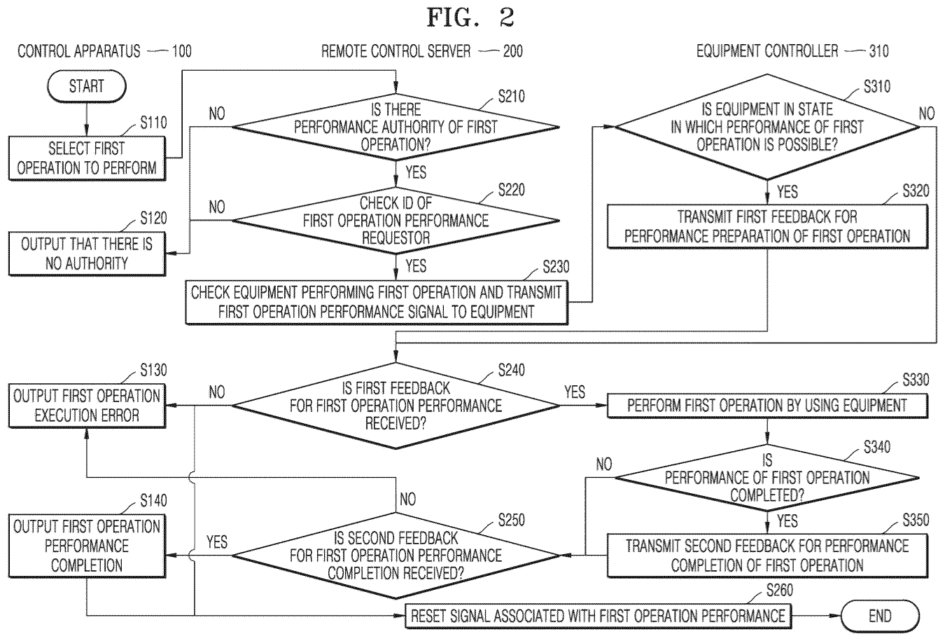

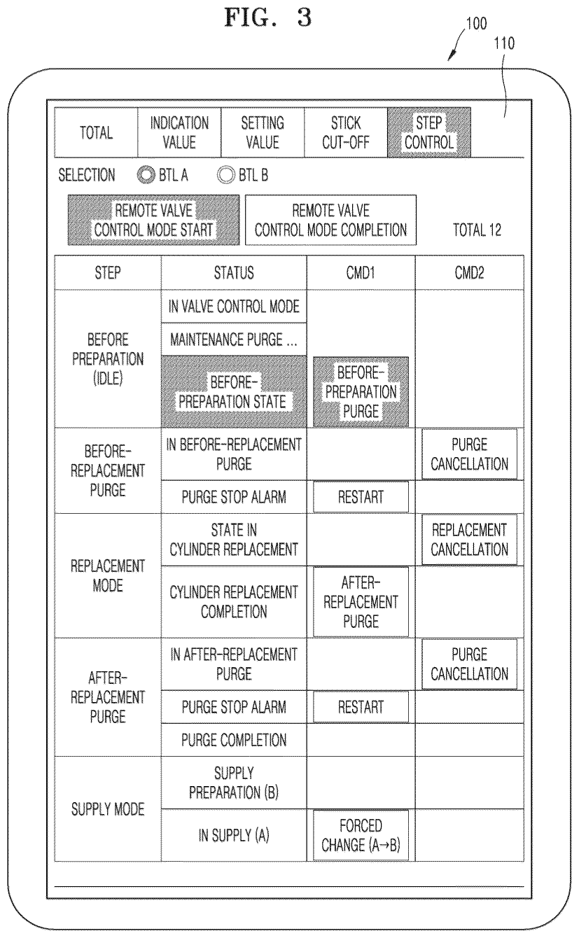

FIG. 1 is a schematic diagram illustrating apparatuses involved in a method of remotely controlling gas supply equipment according to one or more embodiments. FIG. 2 is a flowchart for describing a method of remotely controlling gas supply equipment according to one or more embodiments. FIG. 3 is a diagram illustrating an example of an input/output apparatus for a method of remotely controlling gas supply equipment, according to one or more embodiments.

Referring to FIG. 1, the method of remotely controlling gas supply equipment according to one or more embodiments may be performed between a control apparatus 100, a remote control server 200, and gas supply equipment 300.

The control apparatus 100, for example, may include an output apparatus including a display 110 and may include an input apparatus such as a mouse, a keyboard, or a touch screen enabling an input based on a touch applied to the display 110. The control apparatus 100 may include a display interface for showing to a user, on the display 110, and the display interface may include an interface for a human-machine interaction (HMI) or an interface for providing the user with content provided by an electronic terminal. For example, the display interface may include information processed for visually showing information to the user or information processed related to a user input which is received and processed by the electronic terminal.

The gas supply equipment 300 may include an equipment controller 310. The equipment controller 310 may include, for example, a programmable logic controller (PLC). The equipment controller 310 may be configured with a central processing unit (CPU) for controlling gas supply, a power source which supplies power to the CPU, an analog input (A/I) signal unit, and elements, such as digital signal input (D/I) and output (D/O), for signal transfer and reception. An arithmetic operation for control may be mainly performed by the CPU, and the CPU may control the gas supply equipment 300, based on an installed program.

The remote control server 200 may transmit and receive signals to and from the control apparatus 100, and the remote control server 200 may transmit and receive signals to and from the gas supply equipment 300. That is, the remote control server 200 may function as a relay medium between the control apparatus 100 and the gas supply equipment 300. Signal transmission between the remote control server 200, the control apparatus 100, and the gas supply equipment 300 may be implemented with, for example, wired or wireless networks of all generations including Ethernet, Fibre Channel, InfiniBand, iWARP, transmission control protocol/Internet protocol (TCP/IP), user datagram protocol/IP (UDP/IP), hypertext transfer protocol (HTTP), hypertext transfer protocol secures (HTTPS), RDMA, RDMA over converged Ethernet (RoCE), 2G, 3G, 4G, and 5G, Wi-Fi of all generations, Bluetooth, near field communication (NFC), and/or things similar thereto, or protocols, interfaces, and an arbitrary networking medium each including an arbitrary combination thereof. Particularly, for example, signal transmission between the remote control server 200, the control apparatus 100, and the gas supply equipment 300 may be performed by using TCP/IP.

The control apparatus 100 may remotely control one or more gas supply equipment 300 through the remote control server 200. A plurality of gas supply equipment 300 may be disposed in a large-area space, and the control apparatus 100 may remotely control the plurality of gas supply equipment 300 at positions apart from at least some of the plurality of gas supply equipment 300.

Referring to FIG. 2, a user may select a first operation which is to be performed in the control apparatus 100 in operation S110. In operation S210, the remote control server 200 may check (i.e., identify or determine) whether the user has authority to perform the first operation, on the selected first operation. A process of identifying whether the user has a performance authority of the first operation may be a process where the remote control server 200 identifies a user and checks an authority of the user, based on information about the user input through the control apparatus 100. When the user does not have the authority to perform the first operation, the remote control server 200 may transmit a signal, representing that the user does not have the authority to perform the first operation, to the control apparatus 100. In operation S120, the control apparatus 100 may output that the user lacks authority, based on a signal received from the remote control server 200. The output indicating that the user lacks authority using the control apparatus 100 may be displayed to the user in the form of a pop-up, messages, or an alarm on the display 110 of the control apparatus 100.

A case where the first operation is a “before-replacement purge start” will be described as an example. The expression “before-replacement purge start” may denote an operation of the gas supply equipment including a plurality of gas cylinders performing a purge operation on a pipe of a gas cylinder which is to be replaced, when one or more of the plurality of gas cylinders needs to be replaced because the amount of gas storage of the one or more gas cylinders is low. In this case the plurality of gas cylinders include an A cylinder and a B cylinder (so, a case where two gas cylinders are included in the gas supply equipment 300). The plurality of gas cylinders may store a gas which is supplied from the gas supply equipment to other equipment.

When the user has authority to perform the first operation, the remote control server 200 may check an identification (ID) of a user who has issued a request to perform the first operation in operation S220. When an ID of the user input is found to be inaccurate, or when the user does not have authority to perform the first operation based on identification on the input ID of the user, the remote control server 200 may transmit to the control apparatus 100 a signal representing that the user does not have authority to perform the first operation. In operation S120, the control apparatus 100 may output that there is no authority, based on a signal received from the remote control server 200.

The remote control server 200 may check the ID of the user who has issued the request to perform the first operation in operation S220, and when the user has authority to perform the first operation, the remote control server 200 may check equipment for performing the first operation and may transmit a first operation performance signal to such equipment in operation S230. The equipment controller 310 included in the gas supply equipment 300 may receive the first operation performance signal, and then may check whether the gas supply equipment 300 performing the first operation is in a state capable of the performance of the first operation in operation S310.

The equipment controller 310 may check whether the gas supply equipment 300 is in a state capable of performing the first operation based on an equipment operation allowance condition. The equipment operation allowance condition may be that a state needed for performing each of a plurality of operations, and is classified on each operation. That is, the equipment operation allowance condition may be a set of state conditions which equipment has to satisfy, so as to perform a given operation. Permission conditions may be a set of status conditions that the equipment must satisfy in order for a specific operation to be performed. The equipment operation allowance condition may be stored, for example, in a non-volatile memory provided in the equipment control unit (310).

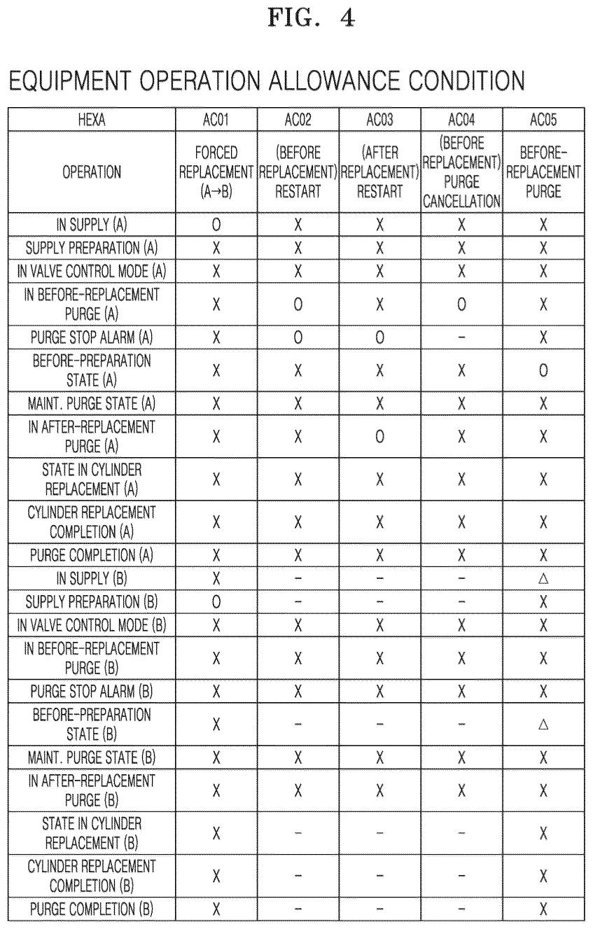

Referring to FIG. 4, for example, for a first operation of “before-replacement purge start” of an A cylinder among two cylinders (for example, the A cylinder and a B cylinder) (namely, when a hexa code value is “before-replacement purge” corresponding to AC05 in a table of FIG. 4), a “before-replacement purge start” operation of the A cylinder may be performed when the A cylinder is in a “before-preparation state”, and when the B cylinder is in a “in-supply state” or “before-preparation state”. Here, a hexa code may be a unique hexadecimal number which is allocated for identifying each operation (e.g., a valve operation).

The equipment operation allowance condition of the “before-replacement purge start” operation of the A cylinder may correspond to a case where the A cylinder has a “before-preparation state”, and the B cylinder has a “in-supply state” or a “before-preparation state”. The equipment operation allowance condition will be described below in more detail with reference to FIG. 4. The hexa code value may vary between embodiments, and the disclosure is not limited by the hexa code values provided in the present disclosure.

When the first operation is in a state capable of being performed by the gas supply equipment 300, the equipment controller 310 may transmit a first feedback, representing that performance of the first operation is ready, to the remote control server 200 in operation S320. When the first operation is not in a state capable of being performed by the gas supply equipment 300, the equipment controller 310 may not transmit a separate signal to the remote control server 200.

When the first feedback is not transmitted from the equipment controller 310 to the remote control server 200, although the remote control server 200 transmits the first operation performance signal to the equipment controller 310, the remote control server 200 may transmit a first operation execution error signal to the control apparatus 100. For example, when an elapsed time, during which the first feedback is not transmitted from the equipment controller 310 to the remote control server 200, is longer than a first setting time, the remote control server 200 may transmit the first operation execution error signal to the control apparatus 100. Simultaneously, the remote control server 200 may initialize signals associated with performance of the first operation in operation S260. The first setting time may be set to, for example, 60 seconds. The first feedback may be a signal including content where the gas supply equipment 300 is ready for performance of the first operation.

When the remote control server 200 receives the first feedback from the equipment controller 310, the remote control server 200 may transmit a signal to the equipment controller 310 initiating performance of the first operation by the gas supply equipment 300. The equipment controller 310 may receive the first operation performance signal and may control the gas supply equipment 300 to perform the first operation. The first operation may consist of a combination of one or more operations including opening or closing a plurality of valves.

For example, when the first operation is a “before-replacement purge start”, a “before-replacement purge start” operation may be performed by closing a valve of a pipe supplied from the A cylinder to the outside and opening a valve for exhausting an internal gas of the A cylinder and a pipe directly connected to the A cylinder.

In operation S340, the equipment controller 310 may identify whether performance of the first operation of the gas supply equipment 300 is completed. When the performance of the first operation of the gas supply equipment 300 is completed, the equipment controller 310 may transmit a second feedback including a signal indicating that performance of the first operation is completed to the remote control server 200.

When the performance of the first operation of the gas supply equipment 300 is not completed, the equipment controller 310 may transmit a signal indicating that the performance of the first operation is not completed to the remote control server 200.

In this case, because the remote control server 200 does not receive the second feedback from the equipment controller 310, the control apparatus 100 may output the first operation execution error, based on a signal of the remote control server 200 in operation S130. Alternatively, even in a case where a second setting time elapses because the performance of the first operation of the gas supply equipment 300 is not completed, when the remote control server 200 does not receive the second feedback from the equipment controller 310, the remote control server 200 may transfer the signal to the control apparatus 100, and the control apparatus 100 may output the first operation execution error, based on the signal of the remote control server 200 in operation S130.

The second setting time may be a reference time taken in performing the first operation of the gas supply equipment 300, and for example, the second setting time may be set to a time which is longer than a time taken in performing the first operation generally.

When the first operation execution error occurs, the control apparatus 100 may record a corresponding error in a log, and the remote control server 200 may transmit an error occurrence alarm to a predetermined manager or to the display 110. Also, when a feedback is not received for a certain time, the control apparatus 100 may automatically cancel an operation and may initialize an equipment state to change to a next command standby state.

When the remote control server 200 receives the second feedback from the equipment controller 310 indicating that the performance of the first operation of the gas supply equipment 300 is completed, the remote control server 200 may allow the control apparatus 100 to output a first operation performance completion in operation S140. The output of the “first operation performance completion” by using the control apparatus 100 may be displayed to the user in the form of a pop-up, messages, or an alarm on the display 110 of the control apparatus 100. Alternatively, the “first operation performance completion” may be displayed by the display 110, or may be output to flicker.

Because the performance of the first operation is completed, signals associated with the performance of the first operation from the equipment controller 310 and the remote control server 200 may be initialized in operation S260. Because the signals associated with the performance of the first operation have been respectively input to the remote control server 200 and the equipment controller 310, each of the remote control server 200 and the equipment controller 310 may be initialized. After an initialization process, the equipment controller 310 may again monitor a current state of the gas supply equipment 300, and the display 110 of the control apparatus 100 may display an operation capable of performance among a plurality of operations, based on the equipment operation allowance condition. A method of displaying an operation capable of performance by using the control apparatus 100 will be described below with reference to FIG. 3.

FIG. 3 illustrates a display interface displayed by the display 110 included in the control apparatus 100. For example, a state of each of two cylinders including the A cylinder and the B cylinder (denoted as “BTL A” and “BTL B”) may be displayed with highlight. For example, as in FIG. 3, a case where the A cylinder is in a “before-preparation state” may be displayed compared to another state. Also, one or more states included in a step may be displayed to be bundled. For example, the “before-preparation state” may be included in a “before-preparation (idle)” step, and thus, may be displayed as a lower item of a “before-preparation (idle)” step item.

When in the “before-preparation state”, an operation capable of being performed by the gas supply equipment 300 may include, for example, “before-replacement purge”. When in a certain state, the remote control server 200 and the equipment controller 310 may determine an operation capable of being performed by the gas supply equipment 300 and may display the determined operation on the display 110 of the control apparatus 100, based on the equipment operation allowance condition of FIG. 4. For example, an operation (for example, “before-replacement purge”) capable of performance may be displayed through a bright background or character so that visibility is greater than, or is highlighted relative to, other operations incapable of performance.

FIG. 4 is a table showing a portion of an equipment operation allowance condition. Descriptions within a range overlapping the above descriptions may be omitted.

In the table of FIG. 4, operations capable of being performed by the gas supply equipment 300 may be displayed on the display 110 of the control apparatus 100, and when a condition is satisfied, the table shows an equipment operation allowance condition which is a criterion for determining that a corresponding operation is capable of performance. The table of FIG. 4 may show forced replacement, restart, purge cancellation, and before-replacement purge as operations, but these are only illustrative examples of operations capable of being performed by the gas supply equipment 300. In addition to the operations shown in FIG. 4, for example, operations such as after-replacement purge, after-replacement purge cancellation, and remote valve individual control may be included therein.

An operation performed by the gas supply equipment 300 may be one of a plurality of all operations including: purge start, purge cancellation, and purge restart before replacing the A cylinder of the gas supply equipment 300; purge start, purge cancellation, and purge restart after replacing the A cylinder of the gas supply equipment 300; purge start, purge cancellation, and purge restart before replacing the B cylinder of the gas supply equipment 300; purge start, purge cancellation, and purge restart after replacing the B cylinder of the gas supply equipment 300; remote valve control; and remote forced replacement.

In such operations, as shown in FIG. 4, for example, a “before-replacement purge” operation of the A cylinder may be performed in a before-preparation state of the A cylinder and an in-supply or before-preparation state of the B cylinder. Therefore, the gas supply equipment 300 performing the first operation described above may determine whether the first operation is in a state capable of performance in operation S310, based on the equipment operation allowance condition of FIG. 4. Alternatively, by continuously monitoring a state of the gas supply equipment 300 with respect to the equipment operation allowance condition of FIG. 4, the remote control server 200 and the equipment controller 310 may operate so that an operation capable of being performed by the gas supply equipment 300 is displayed on the display 110 of the control apparatus 100.

For example, in a case where the “before-replacement purge” operation is being performed by the gas supply equipment 300, when before-replacement purge is being performed (A), based on an equipment operation allowance condition of “(before-replacement) purge cancellation”, a corresponding operation may be performed, and thus, when the “before-replacement purge” operation is performed, the fact that a “(before-replacement) purge cancellation” operation is capable of performance may be displayed on the display 110 of the control apparatus 100. For example, as in FIG. 3, the fact that the “(before-replacement) purge cancellation” operation is capable of performance may be displayed through a background or letters having brightness which is higher than, or are highlighted relative to, other operations.

Equipment operation allowance conditions displayed by “O” may be AND conditions requiring the conditions, and equipment operation allowance conditions displayed by “X” may be NOT AND conditions which do not satisfy the conditions. For example, when an equipment operation allowance condition of the “before-replacement purge” operation of the A cylinder is checked, a before-preparation state (A) may be needed. Also, conditions displayed by “X” such as “in supply (A)” and “in supply preparation (A)” may be a NOT AND condition where all of corresponding conditions are not satisfied.

In addition to an equipment operation allowance condition displayed by “O” or “X”, an equipment operation allowance condition displayed by “-(bar)” may represent a condition irrelevant to a corresponding operation. For example, the “(before-replacement) purge cancellation” operation may be irrelevant to whether an “in supply (B)” state is capable of performance, and thus, may be displayed by “-(bar)”. An equipment operation allowance condition displayed by a triangle may display OR conditions.

For example, “before-replacement purge” may be performed when conditions listed under “before-replacement purge” are all satisfied, and in certain operations, all conditions of the operations may include some OR conditions instead of an AND condition, and this may be set based on an operation needed for the gas supply equipment 300 and an equipment operation allowance condition of the operation. For example, in a certain operation, each of a first operation condition and a second operation condition may be an OR condition. That is, the certain operation may be performed when the first operation condition or the second operation condition is satisfied, or the first operation condition and the second operation condition are simultaneously satisfied.

The foregoing OR condition may be indicated by the symbol “A.” For example, in the case of the “before-replacement purge” operation, the “in-supply (B)” state and the “before-preparation (B)” state, each denoted by A, may correspond to the OR condition. Accordingly, if at least one of the “in-supply (B)” state or the “before-preparation (B)” state is satisfied, one of the conditions for performing the before-replacement purge operation may be fulfilled.

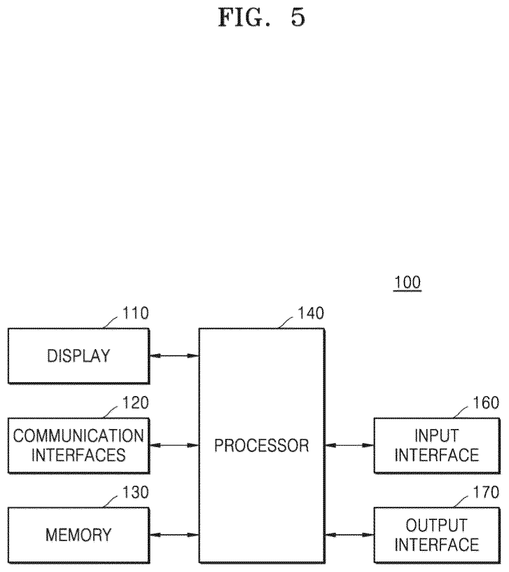

FIG. 5 is a block diagram illustrating a configuration of a control apparatus 100 in a method of remotely controlling gas supply equipment, according to one or more embodiments. Descriptions within a range overlapping the above descriptions may be omitted.

Referring to FIG. 5, in the method of remotely controlling gas supply equipment according to one or more embodiments, the control apparatus 100 may further include a plurality of communication interfaces 120, a memory 130, a processor 140, an input interface 160, and an output interface 170, in addition to a display 110. However, the elements illustrated in FIG. 5 may be merely an embodiment, and in implementing the disclosure, in addition to the elements illustrated in FIG. 5, a new element may be added, or some elements may be omitted.

The input interface 160 may include a circuit, and the processor 140 may receive a user command for controlling an operation of an control apparatus 100 through the input interface 160. In detail, the input interface 160 may be configured with elements such as a mouse, a keyboard, a microphone, and a remote control signal receiver. Also, the input interface 160 may be a touch screen and may be implemented as a type included in the display 110.

The output interface 170 may include a circuit, and the processor 140 may output various functions capable of being performed by the control apparatus 100 through the output interface 170. Also, the output interface 170 may include the display 110.

The display 110 may output image data, based on control by the processor 140. In detail, the display 110 may output an image stored in the memory 130, based on control by the processor 140. Particularly, the display 110 according to one or more embodiments may display a user interface stored in the memory 130. The display 110 may be implemented with a liquid crystal display panel (LCD) or organic light emitting diodes (OLED), and moreover, depending on the case, the display 110 may be implemented as a flexible display 110 or a transparent display 110. However, the display 110 according to one or more embodiments is not limited to a specific kind.

The memory 130 may be implemented as at least one of a volatile memory (e.g.: a dynamic RAM (DRAM), a static RAM (SRAM), or a synchronous dynamic RAM (SDRAM), etc.) or a non-volatile memory (e.g.: an one time programmable ROM (OTPROM), a programmable ROM (PROM), an erasable and programmable ROM (EPROM), an electrically erasable and programmable ROM (EEPROM), a mask ROM, a flash ROM, a flash memory (e.g.: NAND flash or NOR flash, etc.), a hard drive, or a solid state drive (SSD)). In the case of a memory that can be attached to or detached from the control apparatus 100, the memory may be implemented as forms such as a memory card (e.g., compact flash (CF), secure digital (SD), micro secure digital (Micro-SD), mini secure digital (Mini-SD), extreme digital (xD), a multi-media card (MMC), etc.), an external memory that can be connected to a USB port (e.g., a USB memory), etc.

The processor 140 may be implemented as a digital signal processor (DSP) processing digital signals, a microprocessor, and a time controller (TCON). However, the disclosure is not limited thereto, and the processor 140 may include one or more of a central processing unit (CPU), a micro controller unit (MCU), a micro processing unit (MPU), a controller, an application processor (AP), a graphics-processing unit (GPU) or a communication processor (CP), and an advanced reduced instruction set computer (RISC) machines (ARM) processor, or may be defined by the terms. Also, the processor 140 may be implemented as a system on chip (SoC) having a processing algorithm stored therein or large scale integration (LSI), or in the form of a field programmable gate array (FPGA). The processor 140 may perform various functions by individually or collectively executing computer executable instructions stored in the memory. The processor 140 may be provided as a single processor or multiple processors. The processor 140 may be provided with a single core or multiple cores.

In one or more embodiments, the remote control server 200 and the equipment controller 310 may be implemented in a form similar to the control apparatus 100 as shown in FIG. 5. Any one of the control apparatus 100, the remote control server 200, and the equipment controller 310 may include additional components not shown in FIG. 5, or may not include all of the components shown in FIG. 5.

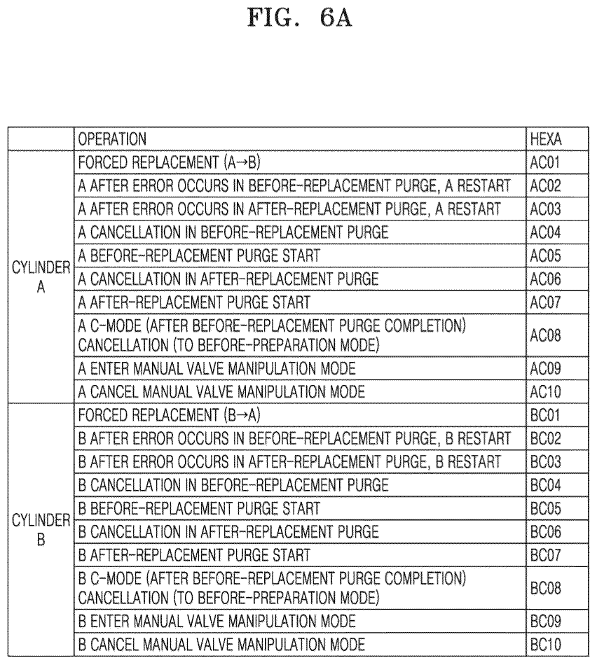

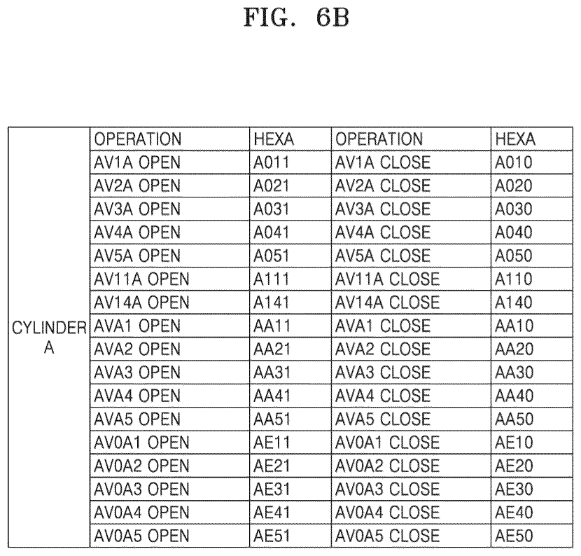

FIGS. 6A and 6B are tables showing exemplary operations capable of being performed in gas supply equipment 300 and hexa codes assigned to the individual operations.

Referring to FIGS. 6A and 6B, in a method of remotely controlling gas supply equipment according to one or more embodiments, hexa codes capable of being distinguished may be respectively assigned to operations and a plurality of individual operations constituting each of the operations.

For example, in “before-replacement purge start of an A cylinder”, AC05 may be set as a hexa code and may be assigned thereto. In the control apparatus 100, the remote control server 200, and the equipment controller 310, an “before-replacement purge start of the A cylinder” operation may be distinguished from other operations through the assigned hexa code AC05, and thus, the “before-replacement purge start of the A cylinder” operation may be performed in the gas supply equipment 300.

In a flowchart for describing the method of remotely controlling the gas supply equipment of FIG. 2 described above, for example, when the first operation is “before-replacement purge start of the A cylinder”, AC05 (which is the hexa code assigned to “before-replacement purge start of the A cylinder” so as to distinguish a requested or performed operation) may be included in a signal transmitted between the control apparatus 100, the remote control server 200, and the equipment controller 310. Operations shown in FIGS. 6A and 6B, and a hexa code assigned to each of the operations, may display only some of all operations. For example, in FIG. 6B, a hexa code based on operations of valves disposed at the A cylinder side is shown, and a hexa code based on an operation of each valve may be assigned to valves disposed at the B cylinder side.

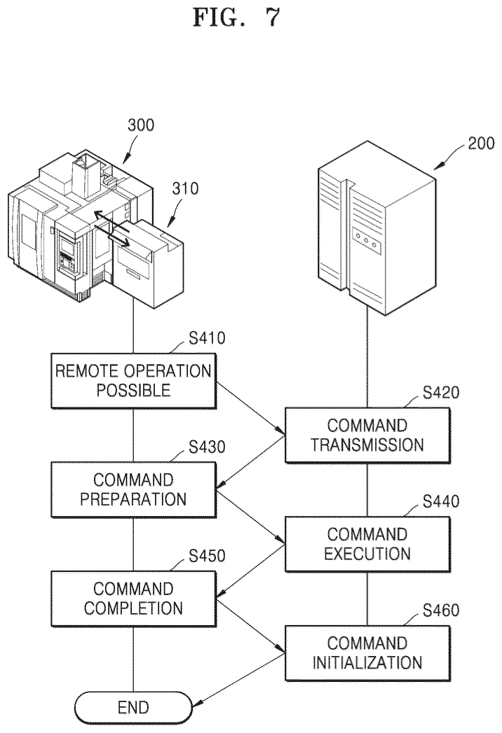

FIG. 7 is a flowchart for describing a method of transferring a signal by using an equipment controller 310 and a remote control server 200 in a remote control method 1 of gas supply equipment, according to one or more embodiments.

Referring to FIG. 7, the equipment controller 310 may transmit a signal, where the gas supply equipment 300 is capable of a remote operation, to the remote control server 200 in operation S410. In a case where the gas supply equipment 300 is capable of performing a certain operation, the gas supply equipment 300 may transmit a signal representing that the certain operation is capable of being remotely performed, and the remote control server 200 which has received a corresponding signal may display, to a user, that the certain operation is in a state capable of performance through the through the display 110 of FIG. 1.

A signal transfer method described above with reference to FIG. 7 may denote a signal transfer method performed between the remote control server 200 and the equipment controller 310 on one or more individual operations included in one operation. In a case where the certain operation is performed by a user, the remote control server 200 may transmit an individual operation, included in the certain operation, to the equipment controller 310. For example, “before-replacement purge” of the A cylinder may be an operation of sequentially performing one or more individual operations such as closing a valve of a pipe connected to the A cylinder and the B cylinder and closing a valve of a pipe connecting the A cylinder to the outside. In addition to the “before-replacement purge” operation of the A cylinder, each of other operations may be an operation where one or more individual operations are complexly performed.

The remote control server 200 which has received a signal capable of a remote operation may transmit a command transmission (S420) signal, allowing the certain operation to be performed, to the equipment controller 310. In a command transmission (S420) operation, the remote control server 200 may transfer a command, a remote hexa code, and an operation hexa code of the gas supply equipment 300 performing the certain operation, to the equipment controller 310 of the gas supply equipment 300 performing the certain operation. The remote hexa code may be a hexa code predetermined for identifying corresponding gas supply equipment 300 and/or equipment controller 310, and the operation hexa code may be a hexa code on an operation needed in the certain operation illustrated in FIG. 6A. The remote hexa code and the operation hexa code may be referred to as a command code.

The equipment controller 310 which has received a command for allowing the certain operation to be performed may transfer a command preparation (S430) signal to the remote control server 200 as a signal where the certain operation is ready. That is, when it is determined that the gas supply equipment 300 is capable of performance of the certain operation, the equipment controller 310 which has received the command transmission (S420) of the certain operation may transfer the command preparation (S430) signal to the remote control server 200. An operation where the equipment controller 310 determines that the gas supply equipment 300 is capable of performance of the certain operation may be determined based on the equipment operation allowance condition of FIG. 4.

The remote control server 200 which has received the command preparation (S430) signal may transmit a command execution (S440) signal, allowing the certain operation to be performed, to the equipment controller 310. The equipment controller 310 which has received the command execution (S440) signal may control the gas supply equipment 300 to perform the certain operation and may transmit a command completion (S450) signal to the remote control server 200 as a signal representing that the performance of the certain operation is completed. Because the remote control server 200 has received the command completion (S450) signal and the certain operation is completed, the remote control server 200 may transmit a signal, initializing (S460) a command associated with the certain operation, to the equipment controller 310 to perform initialization so that each of the equipment controller 310 and the gas supply equipment 300 performs a next operation. A completion hexa code included in the command completion (S450) signal has to be equal to a command code which is added to the command transmission (S420) signal in an operation of transmitting the command transmission (S420) signal.

That is, the remote control server 200 and the equipment controller 310 may transmit and receive transmission signals therebetween so that the individual operations are performed. The transmission signals transmitted and received between the remote control server 200 and the equipment controller 310 may include a remote operation enabling (S410) signal, the command transmission (S420) signal, the command preparation (S430) signal, the command execution (S440) signal, the command completion (S450) signal, and the command initialization (S460) signal each described above. At least one of the transmission signals may include at least one hexa code, and each of the remote control server 200 and the equipment controller 310 may check the hexa code included in signals transmitted and received therebetween and may perform an operation based on the transmission signal when it is determined to be normal.

A method of transferring a signal between the remote control server 200 and the equipment controller 310 described above may be referred to as a signal hand shaking rule between the remote control server 200 and the equipment controller 310. In the method of remotely controlling the gas supply equipment according to one or more embodiments, a risk such as an abnormal operation, an abnormal manipulation, or loss of a signal transmitted through the signal hand shaking rule may be reduced, and thus the reliability of signal transfer of the method of remotely controlling the gas supply equipment may be enhanced.

Also, in the method of remotely controlling the gas supply equipment according to one or more embodiments, a plurality of gas supply equipment 300 may be integrated and may be remotely controlled through one control apparatus 100, and thus, the consumption of human resources may decrease compared to individually controlling the plurality of gas supply equipment 300. Also, the gas supply equipment 300 may be remotely controlled, and thus, the gas supply equipment 300 may be more quickly controlled. Accordingly, the economic feasibility of maintenance of gas supply equipment may be enhanced through the remote control method 1 of the gas supply equipment.

Hereinabove, one or more exemplary embodiments have been described in the drawings and the specification. One or more embodiments have been described by using the terms described herein, but this has been merely used for describing the disclosure and has not been used for limiting a meaning or limiting the scope of the disclosure defined in the following claims. Therefore, it may be understood by those of ordinary skill in the art that various modifications and other equivalent embodiments may be implemented from the disclosure. Accordingly, the spirit and scope of the disclosure may be defined based on the spirit and scope of the following claims.

While the disclosure has been particularly shown and described with reference to one or more embodiments thereof, it will be understood that various changes in form and details may be made therein without departing from the spirit and scope of the following claims.

What is claimed is:

1. A method of remotely controlling gas supply equipment, the method comprising:
checking an operation allowance condition of a first operation of the gas supply equipment using a remote control server;
checking a remote control authority using the remote control server;
checking whether performance of the first operation is possible;
controlling the gas supply equipment to perform the first operation; and
initializing a received signal using the remote control server.

2. The method of claim 1, wherein the checking the operation allowance condition comprises checking the operation allowance condition of each of a plurality of operations including the first operation.

3. The method of claim 1, wherein the checking the operation allowance condition comprises displaying, through a display, the allowance condition of the first operation and an indication of whether performance of the first operation is possible.

4. The method of claim 1, wherein the checking whether the performance of the first operation of the gas supply equipment is possible comprises:
identifying, using the remote control server, the gas supply equipment associated with the first operation;
transmitting, to the gas supply equipment, a first command code corresponding to the first operation; and
transmitting, by the gas supply equipment to the remote control server, a first feedback comprising an indication of whether the performance of the first operation is possible.

5. The method of claim 1, wherein the checking the remote control authority comprises:
based on the remote control authority is absent, outputting an indicator, on a display, that the remote control authority is absent; and
based on the remote control authority being present, checking equipment associated with the first operation and transmitting a first operation performance signal to the gas supply equipment.

6. The method of claim 1, wherein the checking whether the performance of the first operation is possible comprises transmitting a first feedback to the remote control server based on determining that performance of the first operation is possible,
wherein the controlling the gas supply equipment to perform the first operation comprises transmitting a second feedback to the remote control server based on performance of the first operation being completed,
wherein the first feedback comprises a signal indicating that preparation of the first operation is completed, and
wherein the second feedback comprises a signal indicating that performance of the first operation is completed.

7. The method of claim 1, wherein the first operation comprises one or more of a purge start, a purge cancellation, a purge restart, and remote valve control before or after replacement of a cylinder of the gas supply equipment.

8. The method of claim 1, wherein a first code corresponding to the first operation is set and stored in the remote control server and the gas supply equipment, and wherein the first code is used to identify an operation performed by each of the remote control server and the gas supply equipment.

9. The method of claim 8, wherein the first operation comprises a combination of one or more individual operations,
wherein at least one signal transmitted or received between the remote control server and the gas supply equipment comprises a predetermined code indicates that the combination of the one or more individual operations is performed, and
wherein each of the remote control server and the gas supply equipment checks the predetermined code included in the transmitted or received signal.

10. A method of remotely controlling gas supply equipment, the method comprising:
selecting, using a control apparatus, a first operation of the gas supply equipment;
checking, using a remote control server, whether there is authority to perform the first operation;
checking, using an equipment controller, whether performance of the first operation is possible;
transmitting, using the remote control server, a first operation performance signal to the gas supply equipment;
controlling the gas supply equipment to perform the first operation; and
checking, using the equipment controller, whether performance of the first operation is completed.

11. The method of claim 10, wherein the gas supply equipment comprises one or more gas cylinders, and
wherein the first operation comprises at least one of forced replacement, restart, purge cancellation, and before-replacement purge of the one or more gas cylinders.

12. The method of claim 10, wherein the checking whether there is authority to perform the first operation comprises:
based on a user not having authority to perform the first operation, causing the control apparatus to output an indicator that there is no authority; and
based on the user having authority to perform the first operation, transmitting the first operation performance signal to the gas supply equipment.

13. The method of claim 10, wherein the checking whether the performance of the first operation is possible comprises determining, using the equipment controller, whether the performance of the first operation is possible, based on an equipment operation allowance condition related to the first operation, and
wherein the equipment operation allowance condition comprises one or more conditions necessary for performance of the first operation.

14. The method of claim 13, wherein the equipment operation allowance condition comprises one or more states needed for performing the first operation and one or more states which are not needed for performing the first operation, and
wherein the one or more states needed for performing the first operation comprise an AND condition or an OR condition.

15. The method of claim 10, wherein the checking whether the performance of the first operation is possible comprises transmitting a first feedback to the remote control server based on performance of the first operation of the gas supply equipment being possible,
wherein the performing the first operation comprises transmitting a second feedback to the remote control server based on performance of the first operation being completed,
wherein the first feedback comprises a signal indicating that preparation of the first operation is completed, and
wherein the second feedback comprises a signal indicating that performance of the first operation is completed.

16. The method of claim 10, further comprising, after the checking whether the performance of the first operation is completed, initializing a signal associated with the performance of the first operation using the remote control server.

17. The method of claim 10, wherein the checking whether the performance of the first operation is possible comprises transmitting a first feedback to the remote control server based on performance of the first operation of the gas supply equipment being possible, and
wherein the method further comprises, based on the first feedback not being transmitted to the remote control server, transmitting a first operation execution error signal to the control apparatus using the remote control server.

18. The method of claim 17, further comprising transmitting the first operation execution error signal based on a first setting reference time elapsing before the first feedback is transmitted from the equipment controller to the remote control server.

19. The method of claim 10, further comprising:
setting a first code of the first operation;
storing the first code in the remote control server and the gas supply equipment; and
identifying an operation performed by each of the remote control server and the gas supply equipment, based on the first code,
wherein the first operation comprises a combination of one or more individual operations,
wherein at least one signal transmitted or received between the remote control server and the gas supply equipment, to cause the combination of the one or more individual operations to be performed, comprises a predetermined code, and
wherein each of the remote control server and the gas supply equipment is configured to check the predetermined code included in the transmitted or received signal.

20. A method of remotely controlling gas supply equipment, the method comprising:
checking an operation allowance condition of a first operation of the gas supply equipment using a remote control server;
checking a remote control authority using the remote control server;
checking whether performance of the first operation is possible;
controlling the gas supply equipment to perform the first operation; and
initializing a received signal using the remote control server,
wherein the checking the operation allowance condition comprises checking the operation allowance condition of each of a plurality of operations including the first operation, and displaying, through a display, the allowance condition of the first operation and an indication of whether performance of the first operation is possible,
wherein the checking of whether the performance of the first operation is possible comprises:
identifying the gas supply equipment associated with the first operation using the remote control server;
transmitting a first command code, corresponding to the first operation, to the gas supply equipment; and
transmitting, by the gas supply equipment to the remote control server, a first feedback comprising the indication of whether the performance of the first operation is possible,
wherein the checking the remote control authority comprises:
based on there not being remote control authority, outputting an indicator on the display that there is no authority; and
based on there being remote control authority, checking the gas supply equipment associated with the first operation and transmitting a first operation performance signal to the gas supply equipment,
wherein the performing the first operation comprises transmitting a second feedback to the remote control server based on performance of the first operation being completed, the first feedback further comprising a signal that preparation of the first operation is completed, and the second feedback comprising a signal that the performance of the first operation is completed,
wherein the first operation comprises one or more of a purge start, a purge cancellation, a purge restart, and remote valve control before or after replacement of a cylinder of the gas supply equipment,
wherein a first code corresponding to the first operation is set and stored in the remote control server and the gas supply equipment, and the first code is used to identify an operation performed by each of the remote control server and the gas supply equipment,
wherein the first operation further comprises a combination of one or more individual operations, and at least one signal transmitted or received between the remote control server and the gas supply equipment related to performance of the combination of the one or more individual operations comprises a predetermined code, and
wherein each of the remote control server and the gas supply equipment is configured to check the predetermined code included in the transmitted or received signal.
